(19) United States
(12) Patent Application Publication
(10) Pub. No.: US 2024/0222465 A1
(43) Pub. Date: Jul. 4, 2024

(54) SEMICONDUCTOR DEVICE AND MANUFACTURING METHOD THEREFOR

(71) Applicant: Magnachip Semiconductor, Ltd., Cheongju-si (KR)

(72) Inventors: Jungyeon LEE, Seoul (KR); Seongchan JEON, Gumi-si (KR); Kihwan KIM, Seoul (KR); Kitae KANG, Gumi-si (KR); Jiyong LIM, Seoul (KR); Hohyun KIM, Seoul (KR); Chanho PARK, Seoul (KR)

(73) Assignee: Magnachip Semiconductor, Ltd., Cheongju-si (KR)

(21) Appl. No.: 18/449,373

(22) Filed: Aug. 14, 2023

(30) Foreign Application Priority Data
Dec. 29, 2022 (KR) 10-2022-0189429

(51) Int. Cl. H01L 29/49; H01L 21/02; H01L 21/768

(52) U.S. Cl. CPC H01L 29/4941; H01L 21/02186; H01L 21/76864

(57) ABSTRACT

A semiconductor device includes a semiconductor substrate; an oxide film formed on the semiconductor substrate; a gate poly formed on a portion of the oxide film; a spacer formed to surround the gate poly; a dielectric film formed on the spacer; a first barrier metal formed on side surfaces of the oxide film, the gate poly, the spacer, and the dielectric film which are stacked, a surface of the semiconductor substrate, and a top surface of the dielectric film; a second barrier metal formed on the first barrier metal; a metal plug formed in a cavity formed by the second barrier metal; a metal layer formed on the second barrier metal and the metal plug; and a passivation layer formed on the metal layer. A thickness of the first barrier metal formed on the surface of the dielectric film is in a range of from 15 nm to 25 nm.

### CROSS REFERENCE TO RELATED APPLICATION

The application claims the benefit under 35 USC § 119(a) of Korean Patent Application No. 10-2022-0189429, filed Dec. 29, 2022, in the Korean Intellectual Property Office, the entire disclosure of which is incorporated herein by reference for all purposes.

### BACKGROUND

### 1. Field

The following description relates to a semiconductor device and a manufacturing method therefor.

### 2. Description of Related Art

Semiconductor devices are used in almost all electronic devices and are increasingly highly integrated with fine circuitry.

As the line width of circuits decreases in semiconductor devices, a tungsten plug (W-plug) process may be performed for a metal contact area. When tungsten (Ti) and/or tungsten nitride (TiN) are used as a barrier metal, extreme distribution in threshold voltage and instability in threshold voltage may exist after electron irradiation.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a semiconductor device includes a semiconductor substrate; an oxide film formed on the semiconductor substrate; a gate poly formed on a portion of the oxide film; a spacer formed to surround the gate poly; a dielectric film formed on the spacer; a first barrier metal formed on side surfaces of the oxide film, the gate poly, the spacer, and the dielectric film which are stacked, a surface of the semiconductor substrate, and a top surface of the dielectric film; a second barrier metal formed on the first barrier metal; a metal plug formed in a cavity formed by the second barrier metal; a metal layer formed on the second barrier metal and the metal plug; and a passivation layer formed on the metal layer. A thickness of the first barrier metal formed on the top surface of the dielectric film is in a range of from 15 nm to 25 nm.

The semiconductor device may further include a back metal formed on a bottom of the semiconductor substrate.

Portions of the first barrier metal in contact with the semiconductor substrate, the spacer, the oxide film, and portions of the side surfaces of the dielectric film may be silicided.

The first barrier metal may be formed of titanium, the second barrier metal may be formed of titanium nitride, and the metal layer may include aluminum or copper.

A thickness of the second barrier metal formed on the first barrier metal may be in a range of from 70 nm to 90 nm.

In another general aspect, a semiconductor device includes a semiconductor substrate; an oxide film formed on a surface of the semiconductor substrate; a gate poly formed on a portion of the oxide film; a spacer formed to surround the gate poly; a dielectric film formed on the spacer; a barrier metal formed on side surfaces of the oxide film, the gate poly, the spacer, and the dielectric film which are stacked, a surface of the semiconductor substrate, and a top surface of the dielectric film; a metal layer formed on the barrier metal; and a passivation layer formed on the metal layer. A thickness of the barrier metal formed on the top surface of the dielectric film is in a range of from 15 nm to 25 nm.

The semiconductor device may further include a back metal formed on another surface of the semiconductor substrate.

Portions of the barrier metal in contact with the semiconductor substrate, the spacer, the oxide film, and portions of the side surfaces of the dielectric film may be silicided.

The barrier metal may be formed of titanium, and the metal layer may include aluminum or copper.

In another general aspect, a method of manufacturing a semiconductor device includes forming an oxide film on a semiconductor substrate; forming a gate poly on a portion of the oxide film; forming a spacer on the oxide film and the gate poly to surround the gate poly; forming a dielectric film on the spacer; forming a contact area by etching the oxide film, the spacer, and the dielectric film stacked on a side surface of the gate poly; forming a first barrier metal on surfaces of a cavity formed by the contact area and on the dielectric film; forming a second barrier metal on the first barrier metal; forming a metal plug in the cavity of the contact area; forming a metal layer on the metal plug and the second barrier metal; forming a passivation layer on the metal layer; grinding a rear portion of the semiconductor substrate; irradiating electrons onto the semiconductor device; and annealing the semiconductor device.

The annealing of the semiconductor device may include a main annealing operation of performing annealing at a temperature of 330 degrees (° C.) to less than 360 degrees (° C.); and an additional annealing operation of performing annealing at a temperature of 390 degrees (° C.) to less than 410 degrees (° C.).

The method may further include forming aback metal on the rear portion of the semiconductor substrate after the grinding of the rear portion of the semiconductor substrate.

The method may further include performing silicide treatment on the first barrier metal in portions contacting the semiconductor substrate, the spacer, the oxide film, and portions of side surfaces of the dielectric film after the forming of the second barrier metal.

The first barrier metal may be formed of titanium, the second barrier metal may be formed of titanium nitride, and the metal layer may include aluminum or copper.

A thickness of the second barrier metal formed on the first barrier metal may be in a range of from 70 nm to 90 nm.

In another general aspect, a method of manufacturing a semiconductor device includes forming an oxide film on a semiconductor substrate; forming a gate poly on a portion of the oxide film; forming a spacer on the oxide film and the gate poly to surround the gate poly; forming a dielectric film on the spacer; forming a contact area by etching the oxide film, the spacer, and the dielectric film stacked on a side surface of the gate poly; forming a barrier metal on surfaces of a cavity formed by the contact area and on the dielectric film; forming a metal layer on the barrier metal; forming a passivation layer on the metal layer; grinding a rear portion of the semiconductor substrate; irradiating electrons onto the semiconductor device; and annealing the semiconductor device.

The annealing of the semiconductor device may include a main annealing operation of performing annealing at a temperature of 330 degrees (° C.) to less than 360 degrees (° C.), and an additional annealing operation of performing annealing at a temperature of 390 degrees (° C.) to less than 410 degrees (° C.).

The method may further include forming aback metal on the rear portion of the semiconductor substrate after grinding the rear portion of the semiconductor substrate.

The method may further include performing silicide treatment on the barrier metal in portions contacting the semiconductor substrate, the spacer, the oxide film, and portions of side surfaces of the dielectric film after the barrier metal is formed.

The barrier metal may be formed of titanium, and the metal layer may include aluminum or copper.

Other features and aspects will be apparent from the following detailed description, the drawings, and the claims

### BRIEF DESCRIPTION OF THE DRAWINGS

FIG. 1 is a process flow chart illustrating a method of manufacturing a semiconductor device according to one or more embodiments of the present disclosure.

FIGS. 2A to 2J are diagrams describing a method of manufacturing a semiconductor device according to one or more embodiments of the present disclosure.

FIGS. 3A and 3B are diagrams showing average values and standard deviations of threshold voltages according to the thickness of the first barrier metal.

FIG. 4 is a diagram showing standard deviations of threshold voltages according to the thickness of a second barrier metal when the thickness of the first barrier metal is fixed.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment, e.g., as to what an example or embodiment may include or implement, means that at least one example or embodiment exists where such a feature is included or implemented, while all examples are not limited thereto.

Throughout the specification, when a component or element is described as being “on”, “connected to,” “coupled to,” or “joined to” another component, element, or layer it may be directly (e.g., in contact with the other component or element) “on”, “connected to,” “coupled to,” or “joined to” the other component, element, or layer or there may reasonably be one or more other components, elements, layers intervening therebetween. When a component or element is described as being “directly on”, “directly connected to,” “directly coupled to,” or “directly joined” to another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

Due to manufacturing techniques and/or tolerances, variations of the shapes shown in the drawings may occur. Thus, the examples described herein are not limited to the specific shapes shown in the drawings, but include changes in shape that occur during manufacturing.

Unless otherwise defined, all terms, including technical and scientific terms, used herein have the same meaning as commonly understood by one of ordinary skill in the art to which this disclosure pertains specifically in the context on an understanding of the disclosure of the present application. Terms, such as those defined in commonly used dictionaries, are to be interpreted as having a meaning that is consistent with their meaning in the context of the relevant art and specifically in the context of the disclosure of the present application, and are not to be interpreted in an idealized or overly formal sense unless expressly so defined herein.

A term “part” or “module” used in the embodiments may mean software components or hardware components such as a field programmable gate array (FPGA), an application specific integrated circuit (ASIC). The “part” or “module” performs certain functions. However, the “part” or “module” is not meant to be limited to software or hardware. The “part” or “module” may be configured to be placed in an addressable storage medium or to restore one or more processors. Thus, for one example, the “part” or “module” may include components such as software components, object-oriented software components, class components, and task components, and may include processes, functions, attributes, procedures, subroutines, segments of a program code, drivers, firmware, microcode, circuits, data, databases, data structures, tables, arrays, and variables. Components and functions provided in the “part” or “module” may be combined with a smaller number of components and “parts” or “modules” or may be further divided into additional components and “parts” or “modules”.

Methods or algorithm steps described relative to some embodiments of the present disclosure may be directly implemented by hardware and software modules that are executed by a processor or may be directly implemented by a combination thereof. The software module may be resident on a RAM, a flash memory, a ROM, an EPROM, an EEPROM, a resistor, a hard disk, a removable disk, a CD-ROM, or any other type of record medium known to those skilled in the art. An exemplary record medium is coupled to a processor and the processor can read information from the record medium and can record the information in a storage medium. In another way, the record medium may be integrally formed with the processor. The processor and the record medium may be resident within an application specific integrated circuit (ASIC). The ASIC may reside in a user terminal.

Various embodiments of the present disclosure may provide a semiconductor device capable of minimizing variability in threshold voltage and instability in threshold voltage by optimizing the thickness of a barrier metal and a manufacturing method therefor.

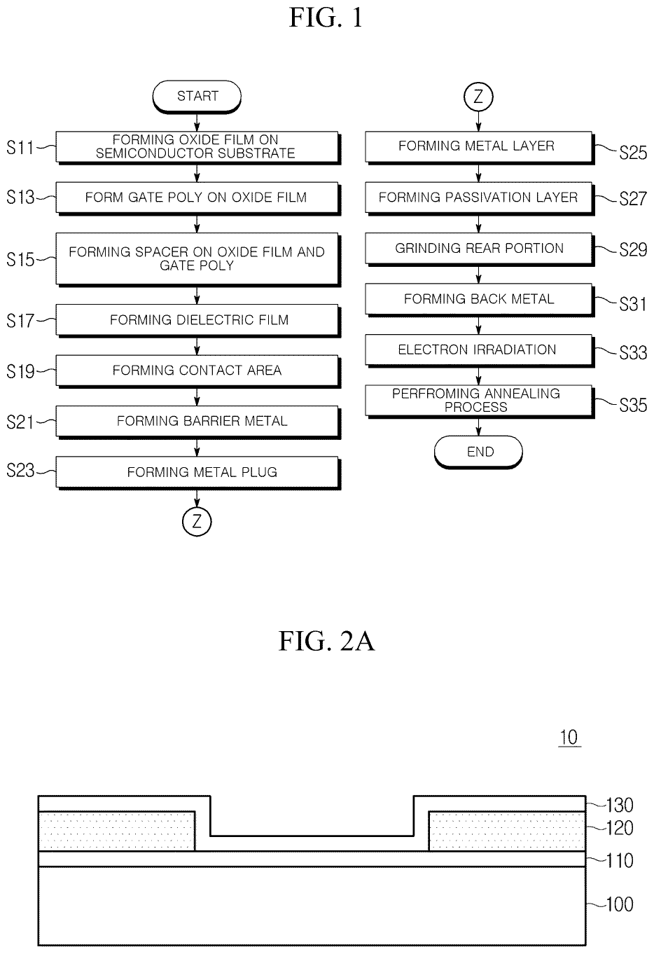

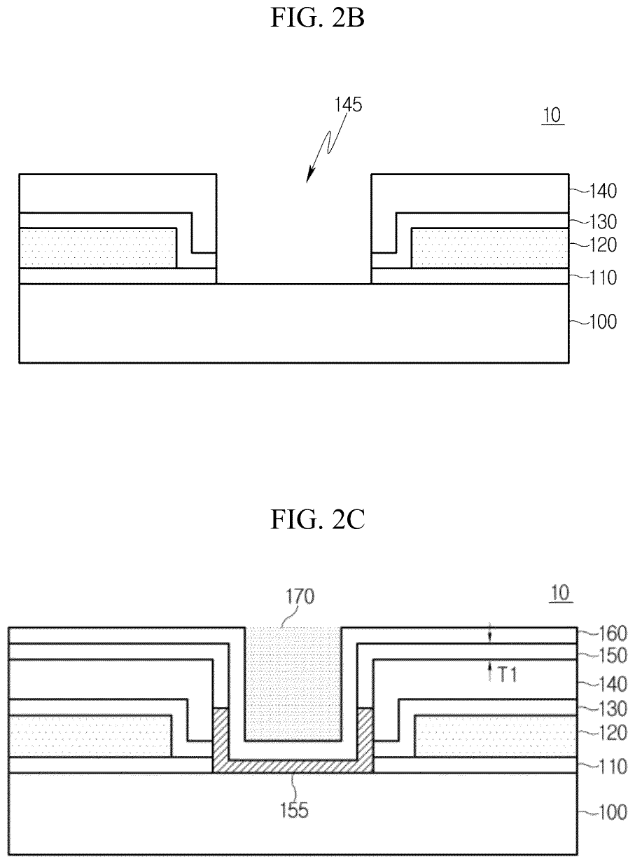

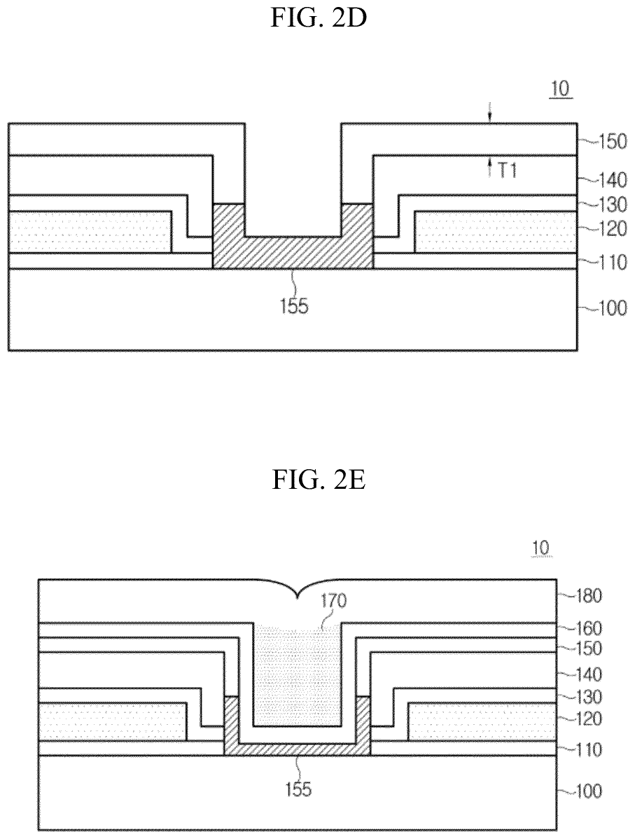

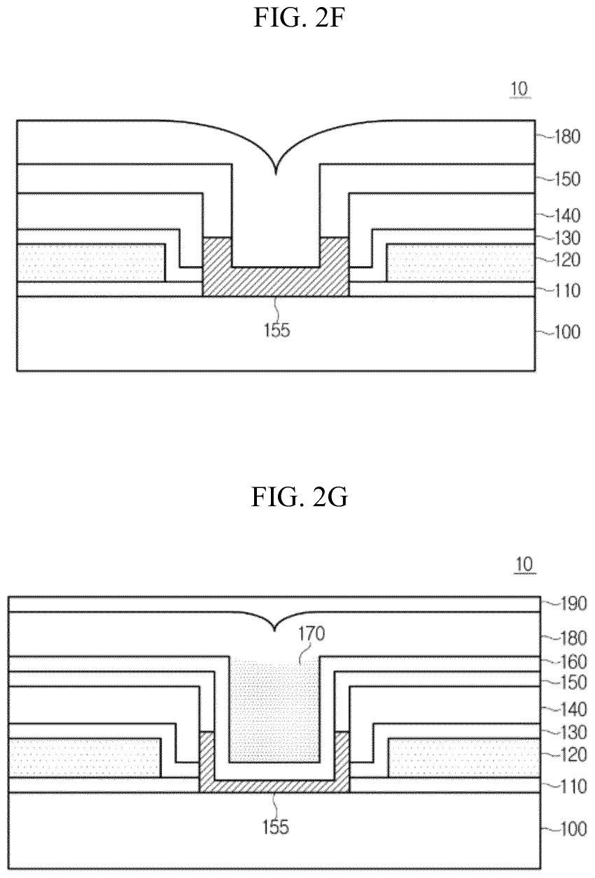

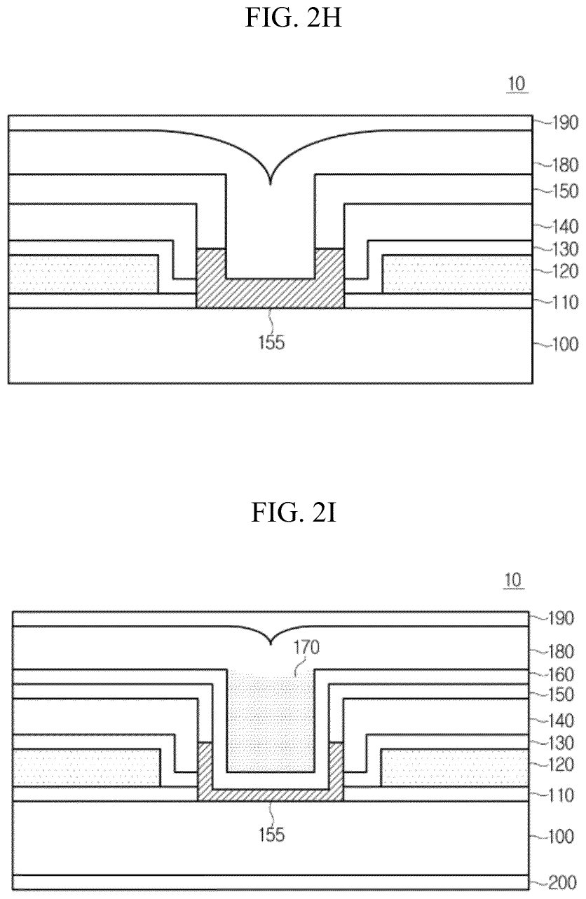

FIG. 1 is a process flow chart illustrating an example of a method of manufacturing a semiconductor device according to one or more embodiments of the present disclosure. FIGS. 2A to 2J are diagrams describing examples of a method of manufacturing a semiconductor device according to one or more embodiments of the present disclosure. In addition, FIGS. 2C, 2E, 2G, and 2I are diagrams showing a case where the line width of a semiconductor device circuit is relatively narrow according to an embodiment of the present disclosure. FIGS. 2D, 2F, 2H and 2J are diagrams showing a case where the line width of a semiconductor device circuit is relatively wide according to another embodiment of the present disclosure.

Referring to FIGS. 1 and 2A, in operation S11, a manufacturing apparatus for manufacturing a semiconductor device 10 may form an oxide film 110 on a semiconductor substrate 100.

In operation S13, the manufacturing apparatus for manufacturing the semiconductor device 10 may form a gate poly 120 on the oxide film 110. According to an embodiment, the gate poly 120 may be applied to the entire area on the oxide film 110, and the gate poly 120 may be formed only in a desired portion through masking and photoresist.

In operation S15, the manufacturing apparatus for manufacturing the semiconductor device 10 may form a spacer 130 on the oxide film 110 and the gate poly 120. In an example, the spacer 130 is an insulating film surrounding an exposed portion of the gate poly 120.

Referring to FIGS. 1 and 2B, in operation S17, the manufacturing apparatus for manufacturing the semiconductor device 10 may form a dielectric film 140 on the spacer 130.

Also, in operation S19, the manufacturing apparatus for manufacturing the semiconductor device 10 may form a contact area 145 in a region between the gate polys 120. The contact area 145 may be formed by forming a predetermined mask pattern on the dielectric film 140, and removing the dielectric film 140, the spacer 130, and the oxide film 110 in which no mask pattern is formed through etching, and then removing the mask pattern. Accordingly, an opening into which a metal material, for example, may be injected may be formed in the contact area 145.

Referring to FIGS. 1, 2C and 2D, in operation S21, the manufacturing apparatus for manufacturing the semiconductor device 10 may include barrier metals, e.g., first and second barrier metals 150 and 160, not only in the inside of the contact area 145 but also on the dielectric film 140.

According to an embodiment, when the line width of the semiconductor device circuit is relatively narrow, as shown in FIG. 2C, a first barrier metal (e.g., titanium (Ti)) 150 and a second barrier metal (e.g., titanium nitride (TiN)) 160 may be sequentially formed to form barrier metals. The thickness of the first barrier metal 150 may be in a range of 15 nm to 25 nm, and the thickness of the second barrier metal 160 may be in a range of 70 nm to 90 nm. In this case, nm is 10⁻⁹ m.

According to another embodiment, when the line width of the semiconductor device circuit is relatively wide, the barrier metal may be formed using only the first barrier metal (e.g., Ti) 150 as shown in FIG. 2D.

After forming the barrier metal, the manufacturing apparatus for manufacturing the semiconductor device 10 may selectively perform a silicide process of the first barrier metal 150. Through the silicide process, a portion where the first barrier metal 150 and the surface of the semiconductor substrate 100 come into contact with each other may be silicided. Therefore, the first barrier metal-silicide (e.g., Ti-silicide) 155 may be formed in the portion where the first barrier metal 150 comes into contact with the semiconductor substrate 100. Also, portions where the first barrier metal 150 contact with the spacer 130, the oxide film 110, and portions of the side surfaces of the dielectric film 140 may be silicided. Therefore, the first barrier metal-silicide 155 may be further formed in the portions where the first barrier metal 150 contact with the spacer 130, the oxide film 110, and portions of the side surfaces of the dielectric film 140.

Referring to FIGS. 2C and 2D, the thickness T1 of the first barrier metal 150 is shown. When the first barrier metal 150 is silicided forming the first barrier metal-silicide 155, a change in thickness may occur. Accordingly, in the present specification, the thickness of the first barrier metal 150 may refer to the thickness of T1 shown in FIGS. 2C and 2D.

Also, in operation S23, when the line width is relatively narrow, a metal plug 170 may be selectively formed on the contact area 145 of FIG. 2B as shown in FIG. 2C. The material used for the metal plug 170 may be tungsten, but is not limited thereto.

Referring to FIGS. 1, 2E and 2F, in operation S25, the manufacturing apparatus for manufacturing the semiconductor device 10 may form a metal layer 180 on the barrier metals 150 and 160 and the contact area 145.

According to an embodiment, as shown in FIG. 2E, when the contact area 145 is filled with the metal plug 170, the metal layer 180 may be formed on the barrier metals 150 and 160 and the metal plug 170.

According to another embodiment, as shown in FIG. 2F, when the contact area 145 is not filled with the metal plug 170, the metal layer 180 may be formed on the barrier metal 150 while filling the contact area 145.

The metal layer 180 may include aluminum or copper, but is not limited thereto.

Referring to FIGS. 1, 2G and 2H, in operation S27, the manufacturing apparatus for manufacturing the semiconductor device 10 may form a passivation layer 190 on the metal layer 180. The passivation layer 190 may serve to protect semiconductor internal circuits. In an example, the passivation layer 190 may be a protective film that may prevent mechanical and chemical damage to internal circuits during subsequent assembly and packaging processes.

Referring to FIG. 1, in operation S29, the manufacturing apparatus for manufacturing the semiconductor device 10 may perform back grinding, which grinds the back of the semiconductor substrate 100 thinly.

Referring to FIGS. 1, 2I and 2J, in operation S31, the manufacturing apparatus for manufacturing the semiconductor device 10 may selectively form a back metal 200 on a surface of the semiconductor substrate 100. The back metal 200 may function as a drain terminal of the semiconductor device 10.

Referring to FIG. 1, in operation S33, the manufacturing apparatus for manufacturing the semiconductor device 10 may perform an electron irradiation process to improve the characteristics of the semiconductor device 10 and perform an annealing process in operation S35.

The annealing process, e.g., in operation S35, may be divided into a first annealing process and a second annealing process. In addition, the first annealing process and the second annealing process may each include a main annealing phase and an additional annealing phase. The main annealing phase may be performed at a temperature of from 330 degrees (° C.) to less than 360 degrees (° C.), and the additional annealing phase may be performed at a temperature of from 390 degrees (° C.) to less than 410 degrees (° C.).

The titanium (Ti) used as the barrier metals 150 and 160 has an ability of capturing hydrogen well due to atomic characteristics. In addition, after the electron irradiation process of operation S33, the annealing process is performed by mixing nitrogen (N2) and hydrogen (H2) during the annealing process of operation S35, and hydrogen may play a role in helping to restore the damaged interface through electron irradiation.

Accordingly, when titanium is formed thicker than a desired thickness, hydrogen molecules are well trapped in titanium, which hinders recovery of the silicon interface, resulting in instability and high dispersion of threshold voltages.

In order to prevent such instability and high dispersion, it may be desirable to optimize the thicknesses of the first barrier metal 150 and the second barrier metal 160.

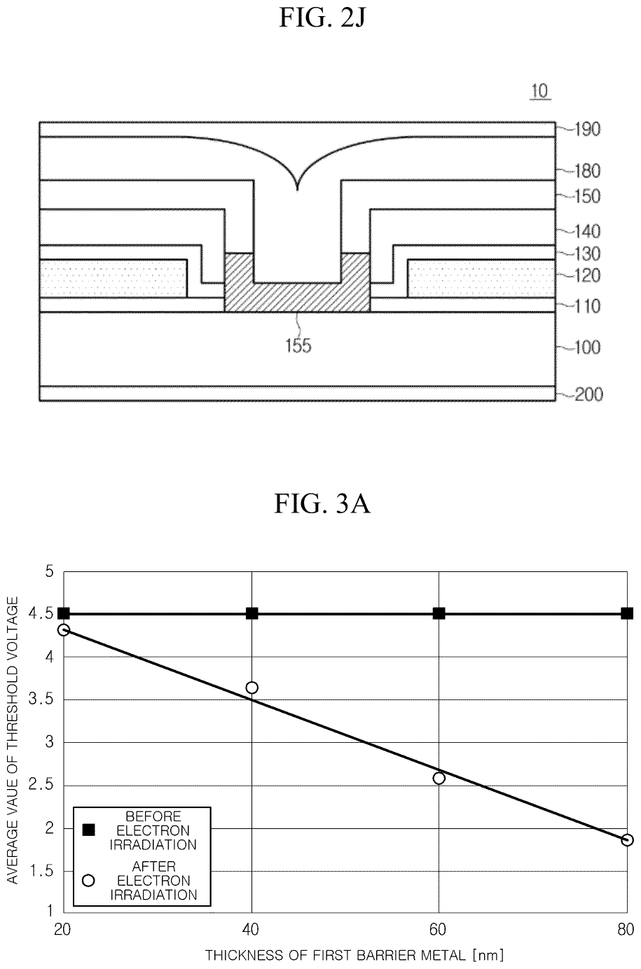

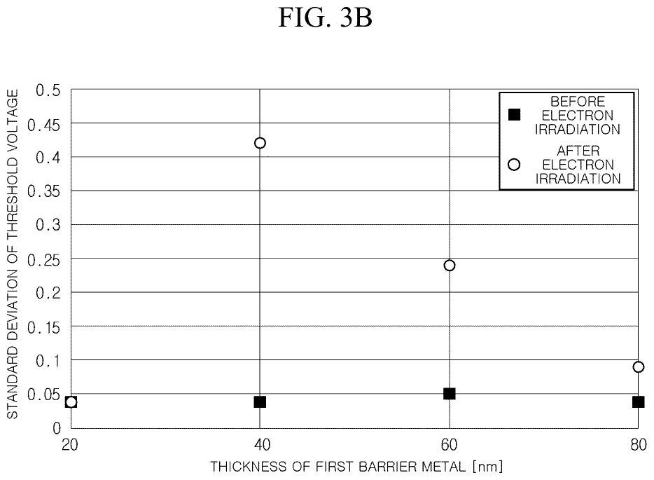

FIGS. 3A and 3B are diagrams showing average values and standard deviations of threshold voltages according to the thickness of the first barrier metal 150.

FIGS. 3A and 3B show the average values and standard deviations of threshold voltages when the thickness of the second barrier metal 160 is held constant at 120 nm and the thickness of the first barrier metal 150 is varied between 20 nm to 80 nm. In FIGS. 3A and 3B, squares represent average values and standard deviations before electron irradiation, and circles represent average values and standard deviations after electron irradiation.

It can be seen from FIGS. 3A and 3B that the average values and standard deviations of threshold voltages before and after electron irradiation are almost similar when the thickness of the first barrier metal 150 is about 20 nm. That is, it can be seen that a change and a distribution in the threshold voltage due to electron irradiation are the smallest when the thickness of the first barrier metal 150 is about 20 nm. On the other hand, it can be seen that the change in the threshold voltage due to electron irradiation increases as the thickness of the first barrier metal 150 increases.

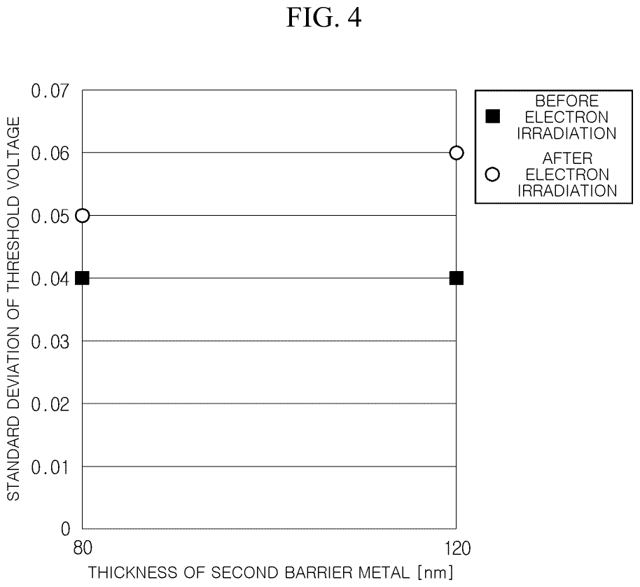

FIG. 4 is a diagram showing standard deviations of threshold voltages when the thickness of the first barrier metal 150 is held constant at about 20 nm and the thickness of the second barrier metal 160 is 80 nm or 120 nm.

As a result of performing test while changing the thickness of the second barrier metal 160 to 80 nm and 120 nm after the thickness of the first barrier metal 150 is fixed to about 20 nm, a case in which the change in the standard deviation of threshold voltages before and after electron irradiation is small is a case in which the thickness of the second barrier metal 160 is about 80 nm.

As described above, the present disclosure can reduce variability in the threshold voltage by using the barrier metal of the semiconductor device with an optimal thickness to improve the instability in the threshold voltage and reduce the dispersion.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A semiconductor device comprising:
a semiconductor substrate;
an oxide film formed on the semiconductor substrate;
a gate poly formed on a portion of the oxide film;
a spacer formed to surround the gate poly;
a dielectric film formed on the spacer;
a first barrier metal formed on side surfaces of the oxide film, the gate poly, the spacer, and the dielectric film which are stacked, a surface of the semiconductor substrate, and a top surface of the dielectric film;
a second barrier metal formed on the first barrier metal;
a metal plug formed in a cavity formed by the second barrier metal;
a metal layer formed on the second barrier metal and the metal plug; and
a passivation layer formed on the metal layer,
wherein a thickness of the first barrier metal formed on the top surface of the dielectric film is in a range of from 15 nm to 25 nm.

2. The semiconductor device of claim 1, further comprising:
a back metal formed on a bottom of the semiconductor substrate.

3. The semiconductor device of claim 1, wherein portions of the first barrier metal in contact with the semiconductor substrate, the spacer, the oxide film, and portions of the side surfaces of the dielectric film is silicided.

4. The semiconductor device of claim 1, wherein the first barrier metal is formed of titanium, the second barrier metal is formed of titanium nitride, and the metal layer includes aluminum or copper.

5. The semiconductor device of claim 1, wherein a thickness of the second barrier metal formed on the first barrier metal is in a range of from 70 nm to 90 nm.

6. A semiconductor device comprising:
a semiconductor substrate;
an oxide film formed on a surface of the semiconductor substrate;
a gate poly formed on a portion of the oxide film;
a spacer formed to surround the gate poly;
a dielectric film formed on the spacer;
a barrier metal formed on side surfaces of the oxide film, the gate poly, the spacer, and the dielectric film which are stacked, a surface of the semiconductor substrate, and a top surface of the dielectric film;
a metal layer formed on the barrier metal; and
a passivation layer formed on the metal layer,
wherein a thickness of the barrier metal formed on the top surface of the dielectric film is in a range of from 15 nm to 25 nm.

7. The semiconductor device of claim 6, further comprising:
a back metal formed on another surface of the semiconductor substrate.

8. The semiconductor device of claim 6, wherein portions of the barrier metal in contact with the semiconductor substrate, the spacer, the oxide film, and portions of the side surfaces of the dielectric film is silicided.

9. The semiconductor device of claim 6, wherein the barrier metal is formed of titanium, and the metal layer includes aluminum or copper.

10. A method of manufacturing a semiconductor device, comprising:
forming an oxide film on a semiconductor substrate;
forming a gate poly on a portion of the oxide film;
forming a spacer on the oxide film and the gate poly to surround the gate poly;
forming a dielectric film on the spacer;
forming a contact area by etching the oxide film, the spacer, and the dielectric film stacked on a side surface of the gate poly;
forming a first barrier metal on surfaces of a cavity formed by the contact area and on the dielectric film;
forming a second barrier metal on the first barrier metal;
forming a metal plug in the cavity of the contact area;
forming a metal layer on the metal plug and the second barrier metal;
forming a passivation layer on the metal layer;
grinding a rear portion of the semiconductor substrate;
irradiating electrons onto the semiconductor device; and
annealing the semiconductor device.

11. The method of claim 10, wherein the annealing of the semiconductor device comprises:
a main annealing operation of performing annealing at a temperature of 330 degrees (° C.) to less than 360 degrees (° C.); and
an additional annealing operation of performing annealing at a temperature of 390 degrees (° C.) to less than 410 degrees (° C.).

12. The method of claim 10, further comprising:
forming a back metal on the rear portion of the semiconductor substrate after the grinding of the rear portion of the semiconductor substrate.

13. The method of claim 10, further comprising:
performing silicide treatment on the first barrier metal in portions contacting the semiconductor substrate, the spacer, the oxide film, and portions of side surfaces of the dielectric film after the forming of the second barrier metal.

14. The method of claim 10, wherein the first barrier metal is formed of titanium, the second barrier metal is formed of titanium nitride, and the metal layer includes aluminum or copper.

15. The method of claim 10, wherein a thickness of the second barrier metal formed on the first barrier metal is in a range of from 70 nm to 90 nm.

16. A method of manufacturing a semiconductor device, comprising:
forming an oxide film on a semiconductor substrate;
forming a gate poly on a portion of the oxide film;
forming a spacer on the oxide film and the gate poly to surround the gate poly;
forming a dielectric film on the spacer;
forming a contact area by etching the oxide film, the spacer, and the dielectric film stacked on a side surface of the gate poly;
forming a barrier metal on surfaces of a cavity formed by the contact area and on the dielectric film;
forming a metal layer on the barrier metal;
forming a passivation layer on the metal layer;
grinding a rear portion of the semiconductor substrate;
irradiating electrons onto the semiconductor device; and
annealing the semiconductor device.

17. The method of claim 16, wherein the annealing of the semiconductor device comprises:
a main annealing operation of performing annealing at a temperature of 330 degrees (° C.) to less than 360 degrees (° C.); and
an additional annealing operation of performing annealing at a temperature of 390 degrees (° C.) to less than 410 degrees (° C.).

18. The method of claim 16, further comprising:
forming a back metal on the rear portion of the semiconductor substrate after grinding the rear portion of the semiconductor substrate.

19. The method of claim 16, further comprising:
performing silicide treatment on the barrier metal in portions contacting the semiconductor substrate, the spacer, the oxide film, and portions of side surfaces of the dielectric film after the barrier metal is formed.

20. The method of claim 16, wherein the barrier metal is formed of titanium, and the metal layer includes aluminum or copper.
